(19) United States
(12) Patent Application Publication
(10) Pub. No.: US 2025/0096094 A1
(43) Pub. Date: Mar. 20, 2025

(54) IO INTERCONNECT CAGE STRUCTURE FOR PACKAGE FORM REDUCTION

(71) Applicant: QUALCOMM Incorporated, San Diego, CA (US)

(72) Inventors: Aniket PATIL, San Diego, CA (US); Piyush GUPTA, San Diego, CA (US); Durodami LISK, San Diego, CA (US)

(21) Appl. No.: 18/468,474

(22) Filed: Sep. 15, 2023

(51) Int. Cl. H01L 23/498; H01L 23/00; H01L 25/065; H05K 1/18

(52) U.S. Cl. CPC H01L 23/49838; H01L 23/49816; H01L 24/16; H01L 24/40; H01L 24/73; H01L 25/0657; H05K 1/181; H01L 2224/16055; H01L 2224/16225; H01L 2224/40091; H01L 2224/40225; H01L 2224/73255; H01L 2225/06517; H01L 2924/1421; H01L 2924/15311; H05K 2201/09227

(57) ABSTRACT

Disclosed are package devices that include interconnects on first and second surfaces of a package substrate. The interconnects on the first surface of the package substrate are configured to carry general purpose input-output (GPIO) and miscellaneous IO signals. The interconnects on the second surface of the package substrate are configured to carry high speed input-output (HSIO) signals-signals whose speeds are above some minimum speed threshold. In this way, the package form can be reduced while still allowing for increased number of IO signals to be delivered.

### FIELD OF DISCLOSURE

This disclosure relates generally to semiconductor devices, and more specifically, but not exclusively, to a novel interconnect cage structure for package form reduction, and fabrication techniques thereof.

### BACKGROUND

Integrated circuit (IC) technology has achieved great strides in advancing computing power through miniaturization of active components. As device technology advances, the input-output (IO) counts are increasing. Every generation has 10-15% more IO counts than preceding generation. Packages are becoming more and more pin count driven. This normally leads to bigger package sizes, which is undesirable.

Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary package device is disclosed. The package device may comprise a package substrate including a first surface, a second surface opposite the first surface, and a peripheral edge. The package device may also comprise a die on a first inner portion the first surface of the package substrate. The first inner portion may be located a first distance away from the peripheral edge of the package substrate. The package device may further comprise a plurality of first substrate interconnects on a first outer portion of the first surface of the package substrate. The first outer portion may surround the first inner portion. The plurality of first substrate interconnects may be electrically coupled to the die. The package device may yet comprise a plurality of second substrate interconnects on a second outer portion of the second surface of the package substrate. The second outer portion may be a portion of the second surface of the package substrate from the peripheral edge to a second distance away from the peripheral edge. The package device may yet further comprise one or more interconnect cages. A first end of each interconnect cage may be coupled to one or more of the first substrate interconnects. Each interconnect cage may be configured to provide electrical coupling between the die and connections outside a physical boundary of the package substrate.

A method of fabricating a package device is disclosed. The method may comprise providing a package substrate including a first surface, a second surface opposite the first surface, and a peripheral edge. The method may also comprise providing a die on a first inner portion the first surface of the package substrate. The first inner portion may be located a first distance away from the peripheral edge of the package substrate. The method may further comprise forming a plurality of first substrate interconnects on a first outer portion of the first surface of the package substrate. The first outer portion may surround the first inner portion. The plurality of first substrate interconnects may be electrically coupled to the die. The method may yet comprise forming a plurality of second substrate interconnects on a second outer portion of the second surface of the package substrate. The second outer portion may be a portion of the second surface of the package substrate from the peripheral edge to a second distance away from the peripheral edge. The method may yet further comprise forming one or more interconnect cages. A first end of each interconnect cage may be coupled to one or more of the first substrate interconnects. Each interconnect cage may be configured to provide electrical coupling between the die and connections outside a physical boundary of the package substrate.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1A illustrates a cross section of a conventional package device.

FIG. 1B illustrates a bottom view of the conventional package device.

FIG. 2A illustrates a cross section of an example package device in accordance with one or more aspects of the disclosure.

FIG. 2B illustrates a bottom view of a package substrate of an example package device in accordance with one or more aspects of the disclosure.

FIG. 3 illustrates a top view of an example package device in accordance with one or more aspects of the disclosure.

FIG. 4 illustrates a top view of another example package device in accordance with one or more aspects of the disclosure.

FIGS. 5A-5B illustrate cross sections of alternative examples of package devices in accordance with one or more aspects of the disclosure.

FIGS. 6A-6D illustrate examples of stages of fabricating a package device in accordance with one or more aspects of the disclosure.

FIGS. 7, 8A and 8B illustrate flow charts of example methods of fabricating a package device in accordance with one or more aspects of the disclosure.

FIG. 9 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises.” “comprising.” “includes,” and/or “including.” when used herein, specify the presence of stated features, integers, steps, operations, elements, and/or components, but do not preclude the presence or addition of one or more other features, integers, steps, operations, elements, components, and/or groups thereof.

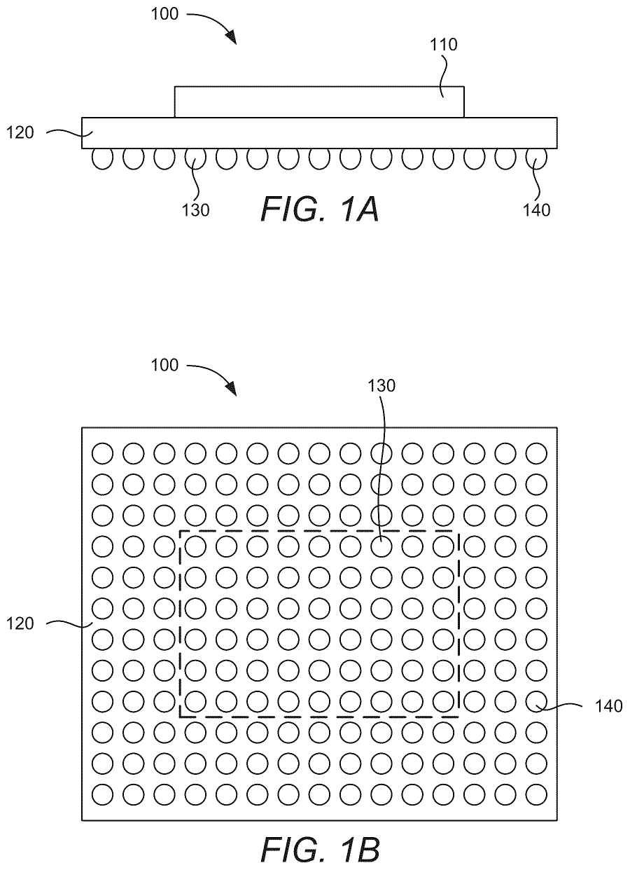

FIG. 1A illustrates a cross section of a conventional package device 100, which includes a die 110 on an upper surface of the package substrate 120. A plurality of balls—IO balls 140, core balls 130—are on a lower surface of the package substrate 120. FIG. 1B illustrates a bottom view of the package substrate 120. The core balls 130 occupy an inner portion (inside the dashed box) of the lower surface of the package substrate 120 and serve as power distribution network (PDN) connections to the die 110. The IO balls 140 occupy an outer portion (outside the dashed box) of the lower surface of the package substrate 120 and provide signal connections to the die 110.

As indicated above, input/output (IO) counts are ever increasing from generation to generation of dies. It is noted that every generation of dies typically has 10-15% more IO than the preceding generation. In FIGS. 1A and 1B, this means that the number IOs increase from generation to generation. As a result, the package is becoming more and more pin count driven, which then leads to bigger and bigger package sizes. This also impacts the printed circuit board (PCB) size. Clearly, it is seen that the package substrate 120 has to increase to accommodate the greater number of IO balls 140. When the package size increases, room for other components such as batteries decrease.

There are generally the following types of IOs—high speed IO (HSIO), general purpose IO (GPIO), and miscellaneous IO. GPIO and miscellaneous IOs are typically not critical in speed (speed integrity (SI)) or power (power integrity (PI)). Thus, in FIGS. 1A and 1B, the IOs include the HSIOs, GPIOs and miscellaneous IOs. That is, all three types of IOs are mixed on the bottom surface of the package substrate 120. This means that there is a limitation on how much the HSIOs can be isolated from interferences from the GPIOs and the miscellaneous IOs.

To address these and other issues of conventional package devices, it is proposed to find alternative ways to connect non-critical IOs (e.g., GPIOs, miscellaneous IOs, etc.) without increasing the package footprint. There can be significant technical advantages in using the proposed approach. They include (not necessarily exhaustive):
Reduce package form factor (e.g., by 20-30%).
Reduce total ball count on package (e.g., by 20-30%).
Save area on PCB, which can lead to (1) make available space for battery size growth, and (2) reduce size of electronic enclosure.
Improve device performance for HSIO signals on package by reducing or eliminating GPIO/miscellaneous IO routes from interfering with HSIO routes.
Enable better layer optimizations on substrate design.
Enable better pin map planning and die friendly FP design.

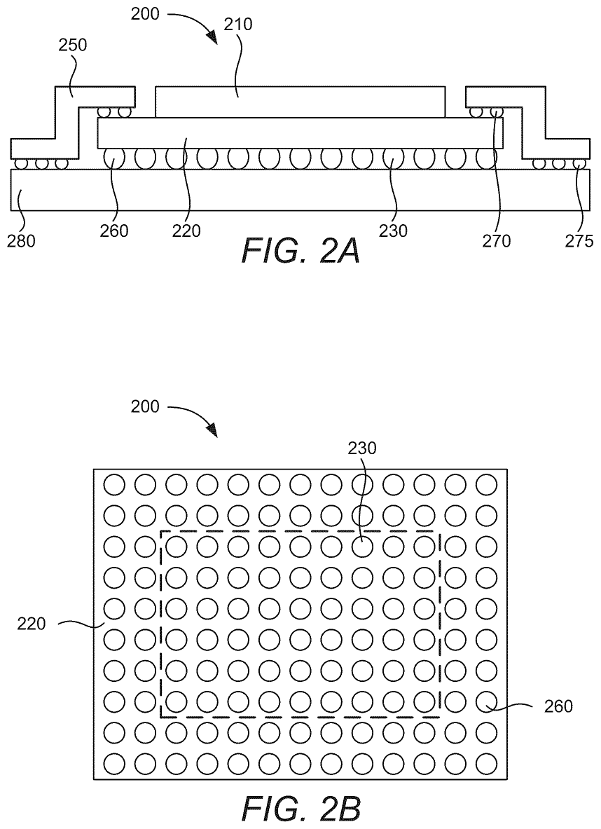

FIG. 2A illustrates a cross section of an example package device 200 in accordance with one or more aspects of the disclosure. The package device 200 may include a package substrate 220, which may include a first surface (e.g., upper surface in FIG. 2A), a second surface (e.g., lower surface in FIG. 2A) opposite the first surface, and a peripheral edge.

The package device 200 may include a die 210 on a first inner portion the first surface of the package substrate 220. The first inner portion may be located a first distance away from the peripheral edge of the package substrate 220.

A plurality of first substrate interconnects 270 may be formed on a first outer portion of the first surface of the package substrate 220. In an aspect, the first outer portion may surround the first inner portion. The plurality of first substrate interconnects 270 may be electrically coupled to the die 210, e.g., through one or more upper metal layers of the package substrate 220 (not shown). In particular, the plurality of first substrate interconnects 270 may be configured to carry non-critical signals (e.g., GPIOs, miscellaneous IOs, etc.) to/from the die 210.

A plurality of power distribution network (PDN) connections 230 and a plurality of second substrate interconnects 260 may be formed on the second surface of the package substrate 220. FIG. 2B illustrates a bottom view of the package substrate 220. The PDN connections 230 may occupy a second inner portion (inside the dashed box). In an aspect, the PDN connections 230 may be configured to serve as power distribution network (PDN) connections to the die 210. That is, they may be configured to carry power and/or ground to the die 210.

The plurality of second substrate interconnects 260 may be formed on a second outer portion (outside the dashed box) of the second surface of the package substrate 220. Some (i.e., one or more) of the second substrate interconnects 260 may be configured to carry HSIO signals. Indeed, in an aspect, all of the second substrate interconnects 260 may be configured to carry the HSIO signals. The HSIO signals may be defined as signals whose speeds are greater than a minimum speed threshold.

Recall that the first substrate interconnects 270 may be configured to carry non-critical signals. Another way of viewing this is that some or all first substrate interconnects 270 may NOT be configured to carry HSIO signals. Thus, the second substrate interconnects 260—which do carry the HSIO signals—may be better isolated from the first substrate interconnects 270. Also, since the lower surface of the package substrate 220 need NOT include pins and connections to carry the GPIO and/or miscellaneous IO, the package form factor and the total ball count can both be reduced, while achieving better signal isolations.

It should be noted that the sizes and/or the shapes of the first and second inner portions of the first and second surfaces of the package substrate 220 can be same or different. This also means that that the sizes and/or the shapes of the first and second outer portions of the first and second surfaces of the package substrate 220 can be same or different. On the first surface of the package substrate 220, the first outer portion may surround the first inner portion. Similarly, on the second surface of the package substrate 220, the second outer portion may surround the lower inner portion.

Referring back to FIG. 2A, the package device 200 may also include one or more interconnect cages 250. A first end of each interconnect cage 250 may be connected one or more of the first substrate interconnects 270. Each interconnect cage 250 may be conductive from/to their first and second ends. That is, each interconnect cage 250 may be configured to provide electrical coupling between the die 210 and connections outside a physical boundary of the package substrate 220.

The package device 200 may further include a printed circuit board (PCB) 280 that includes a first surface (e.g., upper surface), a second surface (e.g., a lower surface), and a peripheral edge. In an aspect, the first surface of the PCB 280 may face the second surface of the package substrate 220. As seen, the package substrate 220 may be placed on the first surface of the PCB 280. The plurality of second substrate interconnects 260 of the package substrate 220 may be electrically coupled to connections of the PCB 280 (not shown).

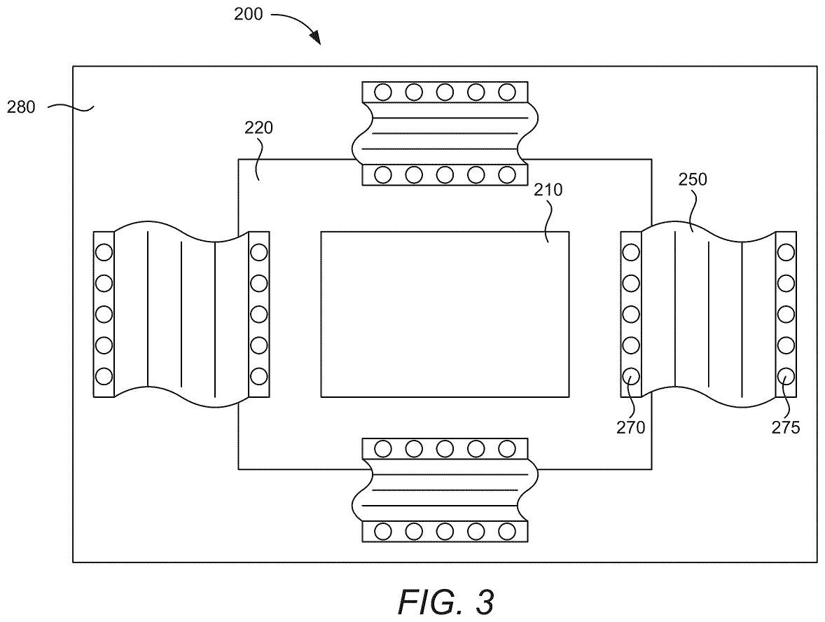

A plurality of PCB interconnects 275 may be formed on the first surface of the PCB 280. The second ends of the interconnect cages 250 may be connected to the PCB interconnects 275. This is also shown in FIG. 3, which illustrates a top view of the package device 200. As seen, there can be multiple interconnect cages 250. Front ends of each interconnect cage 250 are illustrated as being connected to one or more first substrate interconnects 270, and second ends of each interconnect cage 250 are illustrated as being connected to one or more PCB interconnects 275.

In FIG. 3, the interconnect cages 250 are illustrated as being flexible, such as a ribbon. However, this is merely an example and is not a limitation. The interconnect cages 250 can be of any structure that is conductive between first and second ends.

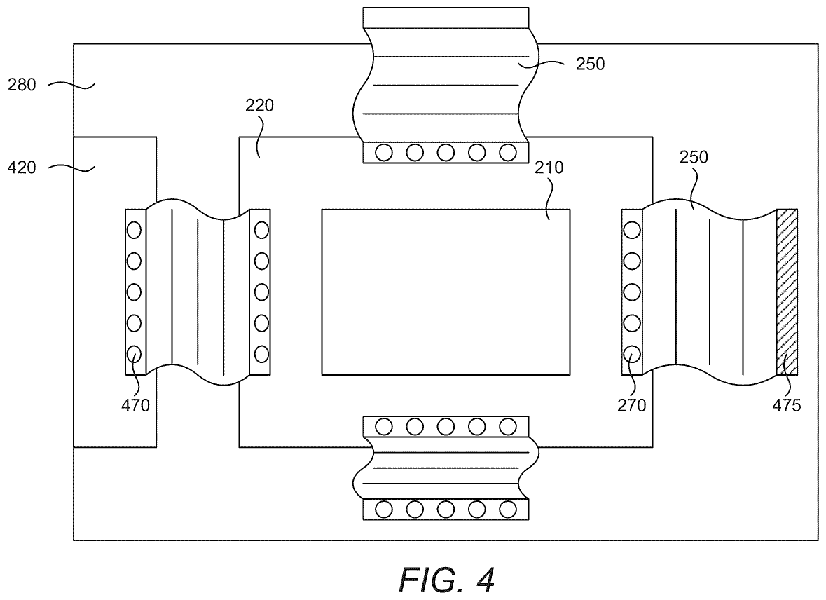

The second ends of the interconnect cages are not limited to just being connected to the PCB interconnects 275. This is shown in FIG. 4, which shows a top view of another example package device. In FIG. 4, four interconnect cages 250 are shown. Note this is merely an example and there can be any number of interconnect cages 250. For ease of reference, the interconnect cages 250 will be ordered starting from the lower interconnect cage and going clockwise. That is, the first, second, third and fourth interconnect cages will respectively refer to lower, left, upper and right interconnect cages.

The first (lower) interconnect cage may be similar to the interconnect cages of FIG. 3. That is, the first interconnect cage may be an interconnect cage whose first end is connected to the one or more first substrate interconnects 270 and whose second end is connected to the one or more PCB interconnects 275.

The second (left) interconnect cage may connect two package substrates. In this particular instance, there may be another package substrate 420 also on the first surface of the PCB 280. Further, a plurality of another first substrate interconnects 470 may be formed on the first (e.g., upper) surface of the second package substrate 420. The first end of the second interconnect cage may be connected to one or more of the first substrate interconnects 270, and the second end of the second interconnect cage may be connected to one or more of the another first substrate interconnects 470.

The third (upper) interconnect cage may extend beyond the boundary of the PCB 280. That is, first end of the third interconnect cage may be connected to the one or more first substrate interconnects 270. The second end of the third interconnect cage may be configured to carry signals to or receive signals from one or more devices physically beyond the PCB 280.

The fourth (right) fourth interconnect cage 250 may provide alternative second end connections. That is, the first end of the fourth interconnect cage may be connected to the one or more first substrate interconnects 270. However, the second end of the fourth interconnect cage 250 may be connected to a connector 475 formed on the first surface of the PCB 280. The connector 475 may be configured to mate with a complementary connector. For example, the connector 475 may be one of male and female, and the complementary connector may be the other of male and female. In another example, the connector 475 may directly physically receive devices such as USB flash drive, memory cards, etc. Alternatively, the connector 475 may mate with a complementary connector that is configured to receive such devices.

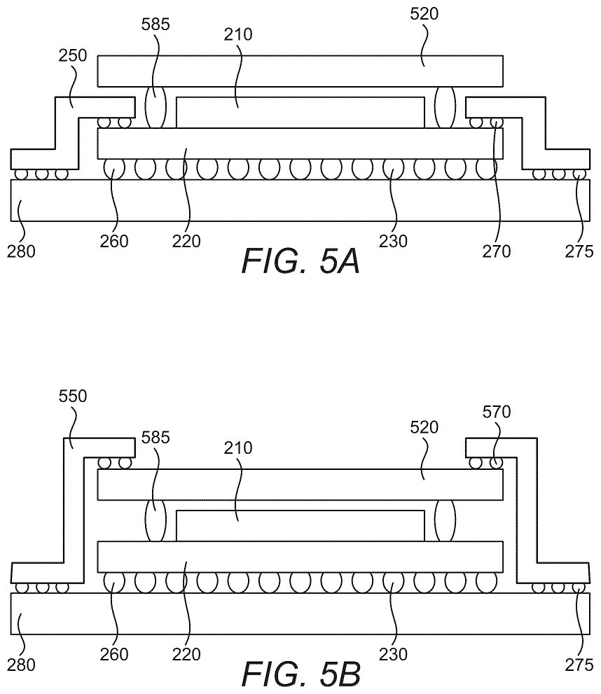

FIG. 5A illustrates a cross section of an alternative embodiment of a package device. In this embodiment, there are two stacked package substrates. That is, the embodiment in FIG. 5A may be similar to the embodiment illustrated in FIG. 2A. However, one difference is that there may be another package substrate 520 above the package substrate 220. For ease of reference, the package substrate 220 may be referred to as a first package substrate and the another package substrate 520 may be referred to as a second package substrate. The package device may further include a plurality of package-to-package connects 585 between the first and second package substrates 220, 520. In an aspect, the package-to-package connects 585 may electrically couple the first and second package substrates 220, 520. While not shown, other devices (e.g., memory die) may be placed above the second package substrate 520.

FIG. 5B illustrates a cross section of another alternative embodiment of a package device. Like the embodiment of FIG. 5A, the embodiment of FIG. 5B may include two stacked package substrates. That is, the second package substrate 520 may be above the first package substrate 220, and the plurality of package-to-package connects 585 may be formed between the first and second package substrates 220, 520.

However, the package device may yet include a plurality of another first substrate interconnects 570 and one or more interconnect cages 550 (different from interconnect cages 250). The plurality of another first substrate interconnects 570 may be formed on the first surface of the second package substrate 520. First ends of the interconnect cages 550 may be connected to one or more of the another first substrate interconnects 570. The second ends may be connected to connections outside the boundary of the second package substrate 520 and/or outside the boundary of the first package substrate 220. Indeed, it may be outside the boundary of the PCB 280. While not shown, there may also be one or more interconnect cages 250 connecting to the first substrate interconnects 270 of the first package substrate 220.

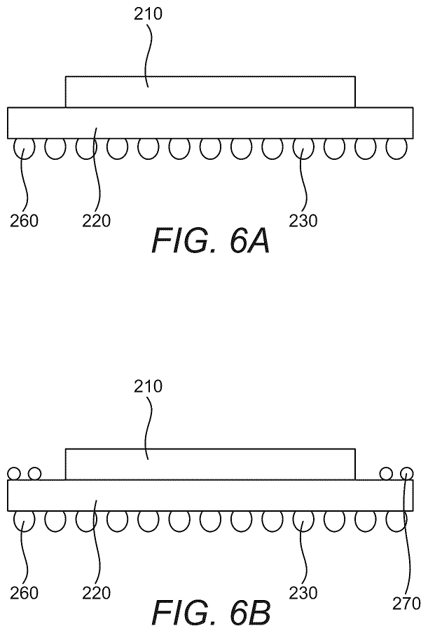

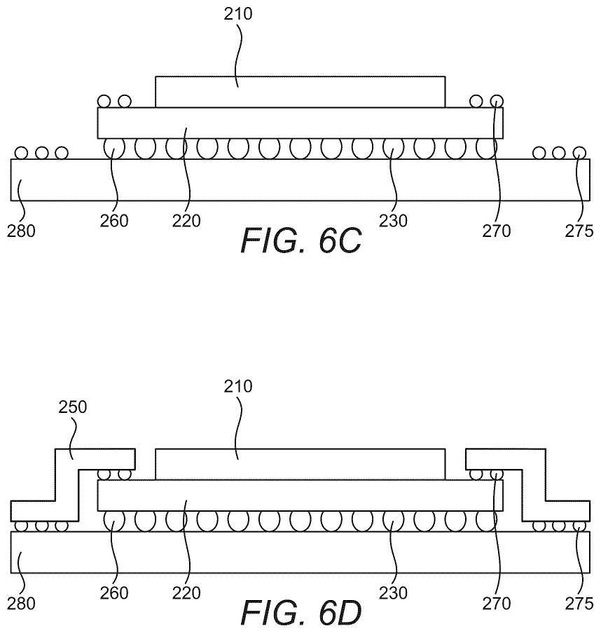

FIGS. 6A-6D illustrate examples of stages of fabricating a package device, such as the package device 200. While not specifically shown, it is relatively straightforward to modify the fabricating process to arrive at the embodiments of FIGS. 5A and 5B. FIG. 6A illustrates a stage in which the package substrate 220 is provided and in which the die 210 is provided on the package substrate 220. The plurality of PDN connections 230 and the plurality second substrate interconnects 260 are also shown as being formed.

FIG. 6B illustrates a stage in which the plurality of first substrate interconnects 270 are formed on the first surface of the package substrate 220.

FIG. 6C illustrates a stage in which the PCB 280 is provided and the plurality of PCB interconnects 275 are formed on the first surface of the PCB 280.

FIG. 6D illustrates a stage in which the interconnect cages 250 are formed.

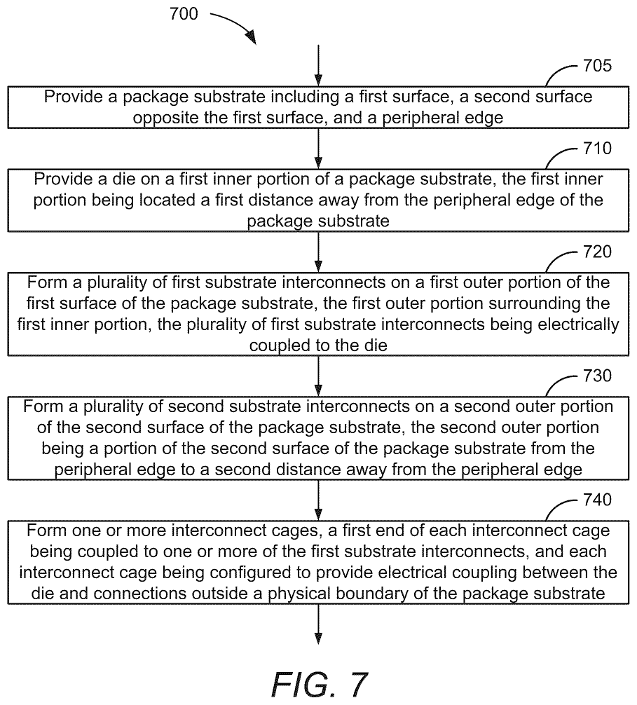

FIG. 7 illustrates a flow chart of an example method 700 of fabricating a package device, such as the package device in accordance with one or more aspects of the disclosure.

In block 705, a package substrate 220 may be provided. The package substrate 220 may include a first surface, a second surface opposite the first surface, and a peripheral edge.

In block 710, a die 210 may be provided on a first inner portion of the package substrate 220. The first inner portion may be located a first distance away from the peripheral edge of the package substrate.

In block 720, a plurality of first substrate interconnects 270 may be formed on a first outer portion of the first surface of the package substrate 220. The first outer portion may surround the first inner portion. The plurality of first substrate interconnects 270 may be electrically coupled to the die 210.

In block 730, a plurality of second substrate interconnects 260 may be formed on a second outer portion of the second surface of the package substrate 220. The second outer portion may be a portion of the second surface of the package substrate 220 from the peripheral edge to a second distance away from the peripheral edge (e.g., the dashed box in FIG. 2B). The plurality of second substrate interconnects 260 may be electrically coupled to the die 210.

In block 740, one or more interconnect cages 250 may be formed. A first end of each interconnect cage 250 may be coupled to one or more of the first substrate interconnects 270. Each interconnect cage 250 may be configured to provide electrical coupling between the die 210 and connections outside a physical boundary of the package substrate 220.

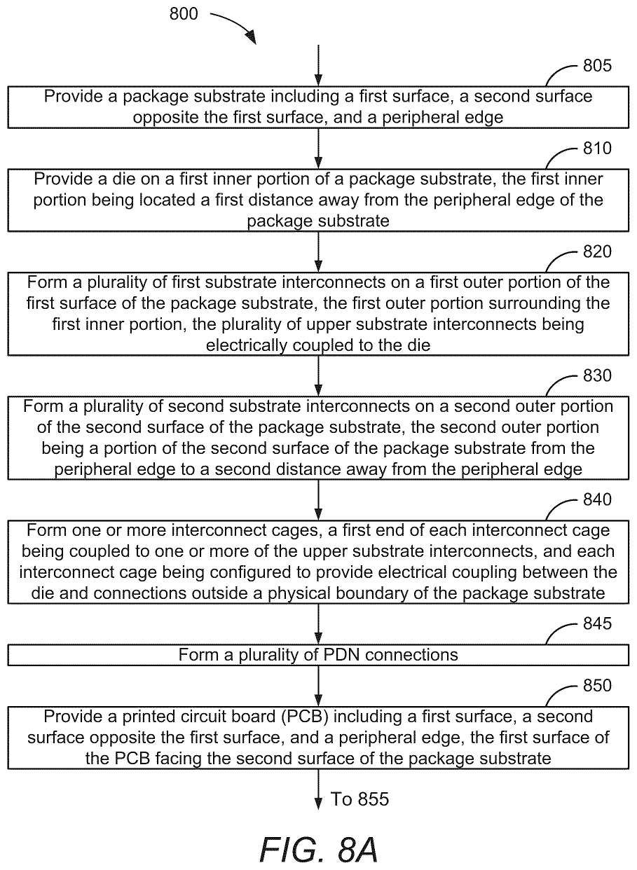

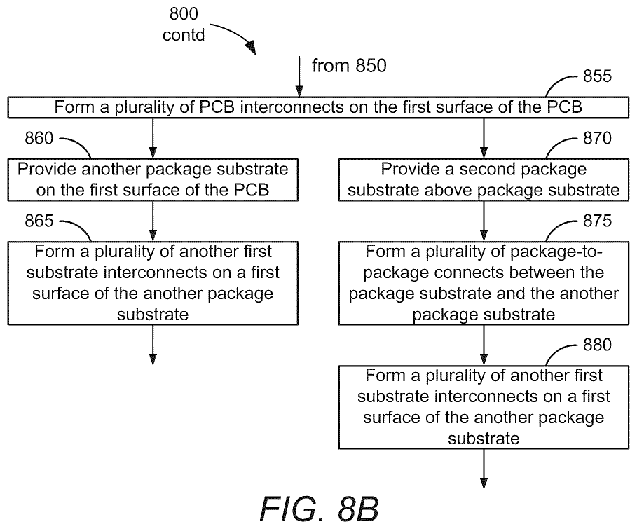

FIGS. 8A and 8B illustrate another flow chart of an example method 800 of fabricating a package device, such as the package device in accordance with one or more aspects of the disclosure. FIGS. 8A and 8B may be viewed as being a more detailed flow chart of FIG. 7.

Block 805 may be similar to block 705. That is, in block 805, a package substrate 220 may be provided. The package substrate 220 may include a first surface, a second surface opposite the first surface, and a peripheral edge.

Block 810 may be similar to block 710. That is, in block 810, a die 210 may be provided on a first inner portion of the package substrate 220. The first inner portion may be located a first distance away from the peripheral edge of the package substrate.

Block 820 may be similar to block 720. That is, in block 820, a plurality of first substrate interconnects 270 may be formed on a first outer portion of the first surface of the package substrate 220. The first outer portion may surround the first inner portion. The plurality of first substrate interconnects 270 may be electrically coupled to the die 210.

Block 830 may be similar to block 730. That is, in block 830, a plurality of second substrate interconnects 260 may be formed on a second outer portion of the second surface of the package substrate 220. The second outer portion may be a portion of the second surface of the package substrate 220 from the peripheral edge to a second distance away from the peripheral edge. The plurality of second substrate interconnects 260 may be electrically coupled to the die 210.

Block 840 may be similar to block 740. That is, in block 840, one or more interconnect cages 250 may be formed. A first end of each interconnect cage 250 may be coupled to one or more of the first substrate interconnects 270. Each interconnect cage 250 may be configured to provide electrical coupling between the die 210 and connections outside a physical boundary of the package substrate 220.

In block 845, a plurality of PDN connections 230 may be formed on a second inner portion of the package substrate 220. The second inner portion may be surrounded by the second outer portion. The plurality of PDN connections 230 may be configured to carry power and/or ground to the die 210.

In block 850, a PCB 280 may be provided. The PCB 280 may include a first surface, a second surface opposite the first surface, and a peripheral. The first surface of the PCB 280 may face the second surface of the package substrate 220.

In block 855, a plurality of PCB interconnects 275 may be formed on the first surface of the PCB 280. That is, the package substrate 220 may be placed on the first surface of the PCB 280. Also, the plurality of second substrate interconnects 260 may be electrically coupled to connections of the PCB 280.

Recall that in FIG. 4, there can be another package substrate 420. In this instance, in block 860, another package substrate 420 may be provided on the first surface of the PCB 280.

In block 865, a plurality of another first substrate interconnects 470 may be formed on the first surface of the another package substrate 420. The one or more interconnect cages 250 may include a second interconnect cage 250 whose first end is connected to one or more of the first substrate interconnects 270, and whose second end is connected to one or more of the another first substrate interconnects 470.

Recall that in FIGS. 5A and 5B, there may be another package substrate 520 above the package substrate 220. In block 870, the another package substrate 520 may be provided above the package substrate 220.

In block 875, a plurality of package-to-package connects 585 may be formed between the package substrate 220 and the another package substrate 520. The package substrate 220 and the another package substrate 520 may also be electrically coupled through the package-to-package connects 585.

In block 880, a plurality of another first substrate interconnects 570 may be formed on the first surface of the another package substrate 520. A first end of the at least one interconnect cage 250 may be connected to one or more of the another first substrate interconnects 570.

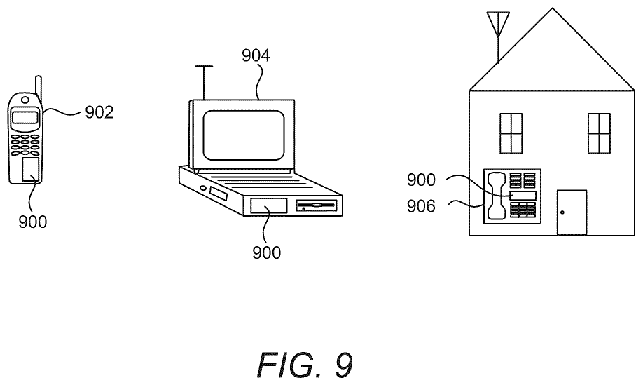

FIG. 9 illustrates various electronic devices 900 that may be integrated with any of the aforementioned package devices in accordance with various aspects of the disclosure. For example, a mobile phone device 902, a laptop computer device 904, and a fixed location terminal device 906 may each be considered generally user equipment (UE) and may include one or more package devices (e.g., package devices 200) as described herein. The devices 902, 904, 906 illustrated in FIG. 9 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A package device, comprising: a package substrate including a first surface, a second surface opposite the first surface, and a peripheral edge; a die on a first inner portion the first surface of the package substrate, the first inner portion being located a first distance away from the peripheral edge of the package substrate; a plurality of first substrate interconnects on a first outer portion of the first surface of the package substrate, the first outer portion surrounding the first inner portion, the plurality of first substrate interconnects being electrically coupled to the die; a plurality of second substrate interconnects on a second outer portion of the second surface of the package substrate, the second outer portion being a portion of the second surface of the package substrate from the peripheral edge to a second distance away from the peripheral edge; and one or more interconnect cages, a first end of each interconnect cage being coupled to one or more of the first substrate interconnects, and each interconnect cage being configured to provide electrical coupling between the die and connections outside a physical boundary of the package substrate.

Clause 2: The package device of clause 1, wherein one or more of the plurality of second substrate interconnects are configured to carry high speed input output (HSIO) signals, which are signal speeds greater than a minimum speed threshold.

Clause 3: The package device of clause 2, wherein all of the plurality of second substrate interconnects are configured to carry HSIO signals.

Clause 4: The package device of any of clauses 2-3, wherein one or more first substrate interconnects are not configured to carry HSIO signals.

Clause 5: The package device of any of clauses 1-4, further comprising: a printed circuit board (PCB) including a first surface, a second surface opposite the first surface, and a peripheral edge, the first surface of the PCB facing the second surface of the package substrate; and a plurality of PCB interconnects on the first surface of the PCB, wherein the plurality of second substrate interconnects are electrically coupled to connections of the PCB.

Clause 6: The package device of clause 5, wherein the one or more interconnect cages includes a first interconnect cage whose first end is connected to the one or more first substrate interconnects and whose second end is connected to one or more PCB interconnects.

Clause 7: The package device of any of clauses 5-6, further comprising: another package substrate on the first surface of the PCB; and a plurality of another first substrate interconnects on a first surface of the another package substrate, wherein the one or more interconnect cages includes another interconnect cage whose first end is connected to one or more of the first substrate interconnects, and wherein a second end of the second interconnect cage is connected to one or more of the another first substrate interconnects.

Clause 8: The package device of any of clauses 5-7, wherein the one or more interconnect cages includes a third interconnect cage whose first end is connected to the one or more first substrate interconnects, and wherein a second end of the third interconnect cage is configured to carry signals to or receive signals from one or more devices physically beyond the PCB.

Clause 9: The package device of any of clauses 5-8, wherein the one or more interconnect cages includes a fourth interconnect cage whose first end is connected to the one or more first substrate interconnects, and wherein a second end of the fourth interconnect cage is connected to a connector formed on the first surface of the PCB, the connector configured to mate with a complementary connector, the connector being one of male and female, and the complementary connector being the other of male and female.

Clause 10: The package device of any of clauses 1-9, further comprising: another package substrate above the package substrate; and a plurality of package-to-package connects between and electrically coupling the package substrate and the another package substrate.

Clause 11: The package device of any of clauses 1-10, further comprising: another package substrate above the package substrate; a plurality of package-to-package connects between the package substrate and the another package substrate; and a plurality of another first substrate interconnects on a first surface of the another package substrate, wherein for at least one interconnect cage, a first end of the at least one interconnect cage is coupled to one or more of the another first substrate interconnects.

Clause 12: The package device of any of clauses 1-11, wherein at least one interconnect cage is flexible.

Clause 13: The package device of any of clauses 1-12, further comprising: a plurality of power distribution network (PDN) connections on a second inner portion of the package substrate, the second inner portion being surrounded by the second outer portion, the plurality of PDN connections being configured to carry power and/or ground to the die.

Clause 14: The package device of any of clauses 1-13, wherein the package device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 15: A method of fabricating a package device, the method comprising: providing a package substrate including a first surface, a second surface opposite the first surface, and a peripheral edge; providing a die on a first inner portion the first surface of the package substrate, the first inner portion being located a first distance away from the peripheral edge of the package substrate; forming a plurality of first substrate interconnects on a first outer portion of the first surface of the package substrate, the first outer portion surrounding the first inner portion, the plurality of first substrate interconnects being electrically coupled to the die; forming a plurality of second substrate interconnects on a second outer portion of the second surface of the package substrate, the second outer portion being a portion of the second surface of the package substrate from the peripheral edge to a second distance away from the peripheral edge; and forming one or more interconnect cages, a first end of each interconnect cage being coupled to one or more of the first substrate interconnects, and each interconnect cage being configured to provide electrical coupling between the die and connections outside a physical boundary of the package substrate.

Clause 16: The method of clause 15, wherein one or more of the plurality of second substrate interconnects are configured to carry high speed input output (HSIO) signals, which are signal speeds greater than a minimum speed threshold.

Clause 17: The method of clause 16, wherein all of the plurality of second substrate interconnects are configured to carry HSIO signals.

Clause 18: The method of any of clauses 16-17, wherein one or more first substrate interconnects are not configured to carry HSIO signals.

Clause 19: The method of any of clauses 15-18, further comprising: providing a printed circuit board (PCB) including a first surface, a second surface opposite the first surface, and a peripheral edge, the first surface of the PCB facing the second surface of the package substrate; and forming a plurality of PCB interconnects on the first surface of the PCB, wherein the plurality of second substrate interconnects are electrically coupled to connections of the PCB.

Clause 20: The method of clause 19, wherein the one or more interconnect cages includes a first interconnect cage whose first end is connected to the one or more first substrate interconnects and whose second end is connected to one or more PCB interconnects.

Clause 21: The method of any of clauses 19-20, further comprising: providing another package substrate on the first surface of the PCB; and forming a plurality of another first substrate interconnects on a first surface of the another package substrate, wherein the one or more interconnect cages includes a second interconnect cage whose first end is connected to one or more of the first substrate interconnects, and wherein a second end of the second interconnect cage is connected to one or more of the another first substrate interconnects.

Clause 22: The method of any of clauses 19-21, wherein the one or more interconnect cages includes a third interconnect cage whose first end is connected to the one or more first substrate interconnects, and wherein a second end of the third interconnect cage is configured to carry signals to or receive signals from one or more devices physically beyond the PCB.

Clause 23: The method of any of clauses 19-22, wherein the one or more interconnect cages includes a fourth interconnect cage whose first end is connected to the one or more first substrate interconnects, and wherein a second end of the fourth interconnect cage is connected to a connector formed on first surface of the PCB, the connector configured to mate with a complementary connector, the connector being one of male and female, and the complementary connector being the other of male and female.

Clause 24: The method of any of clauses 15-23, further comprising: providing another package substrate above the package substrate; and forming a plurality of package-to-package connects between and electrically coupling the package substrate and the another package substrate.

Clause 25: The method of any of clauses 15-24, further comprising: providing another package substrate above the package substrate; forming a plurality of package-to-package connects between the package substrate and the another package substrate; and forming a plurality of another first substrate interconnects on a first surface of the another package substrate, wherein for at least one interconnect cage, a first end of the at least one interconnect cage is coupled to one or more of the another first substrate interconnects.

Clause 26: The method of any of clauses 15-25, wherein at least one interconnect cage is flexible.

Clause 27: The method of any of clauses 15-26, further comprising: forming a plurality of power distribution network (PDN) connections on a second inner portion of the package substrate, the second inner portion being surrounded by the second outer portion, the plurality of PDN connections being configured to carry power and/or ground to the die.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (Wi-Fi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart) is a wireless personal area network technology designed and marketed by the Bluetooth® Special Interest Group intended to provide considerably reduced power consumption and cost while maintaining a similar communication range. BLE was merged into the main Bluetooth® standard in 2010 with the adoption of the Bluetooth® Core Specification Version 4.0 and updated in Bluetooth® 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A package device, comprising:
a package substrate including a first surface, a second surface opposite the first surface, and a peripheral edge;
a die on a first inner portion the first surface of the package substrate, the first inner portion being located a first distance away from the peripheral edge of the package substrate;
a plurality of first substrate interconnects on a first outer portion of the first surface of the package substrate, the first outer portion surrounding the first inner portion, the plurality of first substrate interconnects being electrically coupled to the die;
a plurality of second substrate interconnects on a second outer portion of the second surface of the package substrate, the second outer portion being a portion of the second surface of the package substrate from the peripheral edge to a second distance away from the peripheral edge; and
one or more interconnect cages, a first end of each interconnect cage being coupled to one or more of the first substrate interconnects, and each interconnect cage being configured to provide electrical coupling between the die and connections outside a physical boundary of the package substrate.

2. The package device of claim 1, wherein one or more of the plurality of second substrate interconnects are configured to carry high speed input output (HSIO) signals, which are signal speeds greater than a minimum speed threshold.

3. The package device of claim 2, wherein all of the plurality of second substrate interconnects are configured to carry HSIO signals.

4. The package device of claim 2, wherein one or more first substrate interconnects are not configured to carry HSIO signals.

5. The package device of claim 1, further comprising:
a printed circuit board (PCB) including a first surface, a second surface opposite the first surface, and a peripheral edge, the first surface of the PCB facing the second surface of the package substrate; and
a plurality of PCB interconnects on the first surface of the PCB,
wherein the plurality of second substrate interconnects are electrically coupled to connections of the PCB.

6. The package device of claim 5, wherein the one or more interconnect cages includes a first interconnect cage whose first end is connected to the one or more first substrate interconnects and whose second end is connected to one or more PCB interconnects.

7. The package device of claim 5, further comprising:
another package substrate on the first surface of the PCB; and
a plurality of another first substrate interconnects on a first surface of the another package substrate,
wherein the one or more interconnect cages includes another interconnect cage whose first end is connected to one or more of the first substrate interconnects, and
wherein a second end of the second interconnect cage is connected to one or more of the another first substrate interconnects.

8. The package device of claim 5,
wherein the one or more interconnect cages includes a third interconnect cage whose first end is connected to the one or more first substrate interconnects, and
wherein a second end of the third interconnect cage is configured to carry signals to or receive signals from one or more devices physically beyond the PCB.

9. The package device of claim 5,
wherein the one or more interconnect cages includes a fourth interconnect cage whose first end is connected to the one or more first substrate interconnects, and
wherein a second end of the fourth interconnect cage is connected to a connector formed on the first surface of the PCB, the connector configured to mate with a complementary connector, the connector being one of male and female, and the complementary connector being the other of male and female.

10. The package device of claim 1, further comprising:
another package substrate above the package substrate; and
a plurality of package-to-package connects between and electrically coupling the package substrate and the another package substrate.

11. The package device of claim 1, further comprising:
another package substrate above the package substrate;
a plurality of package-to-package connects between the package substrate and the another package substrate; and
a plurality of another first substrate interconnects on a first surface of the another package substrate,
wherein for at least one interconnect cage, a first end of the at least one interconnect cage is coupled to one or more of the another first substrate interconnects.

12. The package device of claim 1, wherein at least one interconnect cage is flexible.

13. The package device of claim 1, further comprising:
a plurality of power distribution network (PDN) connections on a second inner portion of the package substrate, the second inner portion being surrounded by the second outer portion, the plurality of PDN connections being configured to carry power and/or ground to the die.

14. The package device of claim 1, wherein the package device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

15. A method of fabricating a package device, the method comprising:
providing a package substrate including a first surface, a second surface opposite the first surface, and a peripheral edge;
providing a die on a first inner portion the first surface of the package substrate, the first inner portion being located a first distance away from the peripheral edge of the package substrate;
forming a plurality of first substrate interconnects on a first outer portion of the first surface of the package substrate, the first outer portion surrounding the first inner portion, the plurality of first substrate interconnects being electrically coupled to the die;
forming a plurality of second substrate interconnects on a second outer portion of the second surface of the package substrate, the second outer portion being a portion of the second surface of the package substrate from the peripheral edge to a second distance away from the peripheral edge; and
forming one or more interconnect cages, a first end of each interconnect cage being coupled to one or more of the first substrate interconnects, and each interconnect cage being configured to provide electrical coupling between the die and connections outside a physical boundary of the package substrate.

16. The method of claim 15, wherein one or more of the plurality of second substrate interconnects are configured to carry high speed input output (HSIO) signals, which are signal speeds greater than a minimum speed threshold.

17. The method of claim 16, wherein all of the plurality of second substrate interconnects are configured to carry HSIO signals.

18. The method of claim 16, wherein one or more first substrate interconnects are not configured to carry HSIO signals.

19. The method of claim 15, further comprising:
providing a printed circuit board (PCB) including a first surface, a second surface opposite the first surface, and a peripheral edge, the first surface of the PCB facing the second surface of the package substrate; and
forming a plurality of PCB interconnects on the first surface of the PCB,
wherein the plurality of second substrate interconnects are electrically coupled to connections of the PCB.

20. The method of claim 19, wherein the one or more interconnect cages includes a first interconnect cage whose first end is connected to the one or more first substrate interconnects and whose second end is connected to one or more PCB interconnects.

21. The method of claim 19, further comprising:
providing another package substrate on the first surface of the PCB; and
forming a plurality of another first substrate interconnects on a first surface of the another package substrate,
wherein the one or more interconnect cages includes a second interconnect cage whose first end is connected to one or more of the first substrate interconnects, and
wherein a second end of the second interconnect cage is connected to one or more of the another first substrate interconnects.

22. The method of claim 19,
wherein the one or more interconnect cages includes a third interconnect cage whose first end is connected to the one or more first substrate interconnects, and
wherein a second end of the third interconnect cage is configured to carry signals to or receive signals from one or more devices physically beyond the PCB.

23. The method of claim 19,
wherein the one or more interconnect cages includes a fourth interconnect cage whose first end is connected to the one or more first substrate interconnects, and
wherein a second end of the fourth interconnect cage is connected to a connector formed on the first surface of the PCB, the connector configured to mate with a complementary connector, the connector being one of male and female, and the complementary connector being the other of male and female.

24. The method of claim 15, further comprising:
providing another package substrate above the package substrate; and
forming a plurality of package-to-package connects between and electrically coupling the package substrate and the another package substrate.

25. The method of claim 15, further comprising:
providing another package substrate above the package substrate;
forming a plurality of package-to-package connects between the package substrate and the another package substrate; and
forming a plurality of another first substrate interconnects on a first surface of the another package substrate,
wherein for at least one interconnect cage, a first end of the at least one interconnect cage is coupled to one or more of the another first substrate interconnects.

26. The method of claim 15, wherein at least one interconnect cage is flexible.

27. The method of claim 15, further comprising:
forming a plurality of power distribution network (PDN) connections on a second inner portion of the package substrate, the second inner portion being surrounded by the second outer portion, the plurality of PDN connections being configured to carry power and/or ground to the die.
